(19) United States
(12) Patent Application Publication
(10) Pub. No.: US 2025/0338619 A1
(43) Pub. Date: Oct. 30, 2025

(54) PIXEL, METHOD OF MANUFACTURING THE PIXEL, AND ELECTRONIC DEVICE INCLUDING THE PIXEL

(71) Applicant: Samsung Display Co., LTD., Yongin-si (KR)

(72) Inventors: Thanh Tien NGUYEN, Yongin-si (KR); Sang Gun CHOI, Yongin-si (KR); Myoung Geun CHA, Yongin-si (KR); Han Bit KIM, Yongin-si (KR); Hee Sung YANG, Yongin-si (KR)

(73) Assignee: Samsung Display Co., LTD., Yongin-si (KR)

(21) Appl. No.: 19/029,951

(22) Filed: Jan. 17, 2025

(30) Foreign Application Priority Data
Apr. 25, 2024 (KR) 10-2024-0055591

(51) Int. Cl. H10D 86/40; H10D 64/01; H10D 64/23; H10D 86/01; H10D 86/60

(52) U.S. Cl. CPC H10D 86/441; H10D 64/01; H10D 64/251; H10D 86/0212; H10D 86/451; H10D 86/481; H10D 86/60

(57) ABSTRACT

Provided is a pixel including a first pattern disposed on a substrate, a lower insulating layer array including a lower penetration hole exposing a portion of the first pattern, a second pattern which is electrically in contact with the first pattern through the lower penetration hole and includes a recessed portion overlapping the lower penetration hole, a buffer layer filling the recessed portion, a protective layer interposed between the buffer layer and the second pattern in the recessed portion, an auxiliary conductive layer which overlaps the lower penetration hole in a thickness direction and covers the buffer layer and the second pattern adjacent to the buffer layer, an upper insulating layer array including an upper penetration hole exposing a portion of the auxiliary conductive layer, and a third pattern electrically in contact with the auxiliary conductive layer through the upper penetration hole.

### CROSS-REFERENCE TO RELATED APPLICATION

The present application claims priority under 35 U.S.C. § 119(a) to Korean patent application No. 10-2024-0055591 filed on Apr. 25, 2024 in the Korean Intellectual Property Office, the entire disclosure of which is incorporated herein by reference.

### BACKGROUND

### 1. Technical Field

The disclosure relates to a pixel, a method of manufacturing the pixel, and an electronic device including the pixel.

### 2. Description of the Related Art

Multiple pixels may be present in a display device. Each of the plurality of pixels may emit light. The display device may combine the light output from the several pixels to display an image.

Each of the plurality of pixels may include a pixel circuit and at least one light emitting element electrically connected to the pixel circuit. The pixel circuit may include a plurality of conductive layers and one or two or more semiconductor layers. The conductive layers and/or the semiconductor layers may be electrically separated from each other by one or two or more insulating layers interposed therebetween. A penetration hole defined in the insulating layers may allow the conductive and/or semiconductor layers to be electrically connected to one another in a partial location. The conductive layers and/or the semiconductor layers may constitute a transistor, a line, an electrode, a capacitor, and the like of the pixel circuit.

### SUMMARY

Embodiments provide a pixel having improved reliability and a method of manufacturing the pixel.

In accordance with an aspect of the disclosure, there is provided a pixel including: a first pattern disposed on a substrate; a lower insulating layer array including a lower penetration hole exposing a portion of the first pattern; a second pattern electrically in contact with the first pattern through the lower penetration hole, the second pattern including a recessed portion overlapping the lower penetration hole; a buffer layer filling the recessed portion; a protective layer interposed between the buffer layer and the second pattern in the recessed portion; an auxiliary conductive layer overlapping the lower penetration hole in a thickness direction, the auxiliary conductive layer covering the buffer layer and the second pattern adjacent to the buffer layer; an upper insulating layer array including an upper penetration hole exposing a portion of the auxiliary conductive layer; and a third pattern electrically in contact with the auxiliary conductive layer through the upper penetration hole.

The lower penetration hole and the upper penetration hole may be disposed and overlapped each other in a plan view.

An upper surface of the lower insulating layer array may be substantially flat.

The protective layer may include a material different from a material of the second pattern.

The protective layer may include a metal oxide.

An upper surface of the buffer layer may be positioned higher than an upper surface of the second pattern.

A thickness between the upper surface of the buffer layer and the upper surface of the second pattern may be smaller than a thickness of the protective layer.

Each of the lower insulating layer array and the upper insulating layer array may include two or more insulating layers which are sequentially stacked in the thickness direction.

Each of the first to third patterns may include a conductive material.

The first pattern may include a semiconductor material doped with an impurity to have conductivity.

In accordance with another aspect of the disclosure, there is provided a method of manufacturing a pixel, the method including: forming a first pattern on a substrate; forming a lower insulating layer array on the first pattern; selectively etching the lower insulating layer array to include a lower penetration hole exposing a portion of the first pattern; forming a second pattern on the lower insulating layer array to electrically contact the first pattern through the lower penetration hole, the second pattern including a recessed portion corresponding to the lower penetration hole; forming a protective layer on the second pattern to entirely cover the second pattern; forming a buffer layer on the protective layer to entirely cover the protective layer and to fill the recessed portion; removing a portion of the buffer layer such that an upper surface of the protective layer is exposed; removing the protective layer except a portion interposed between the buffer layer and the second pattern in the recessed portion by selectively patterning the protective layer; forming an auxiliary conductive layer on the second pattern to overlap the lower penetration hole in a thickness direction, the auxiliary conductive layer covering the buffer layer and the second pattern adjacent to the buffer layer; forming an upper insulating layer array on the second pattern and the auxiliary conductive layer; selectively etching the upper insulating layer array to define an upper penetration hole exposing a portion of the auxiliary conductive layer; and forming a third pattern on the upper insulating layer array to electrically contact the auxiliary conductive layer through the upper penetration hole.

The lower penetration hole and the upper penetration hole may be disposed and overlapped each other in a plan view.

The forming of the lower insulating layer array may include planarizing an upper surface of the lower insulating layer array.

In the removing of the buffer layer, an upper surface of the second pattern may not be exposed.

An upper surface of the buffer layer may be positioned higher than an upper surface of the second pattern.

A thickness between the upper surface of the buffer layer and the upper surface of the second pattern may be smaller than a thickness of the protective layer.

Each of the lower insulating layer array and the upper insulating layer array may include two or more insulating layers which are sequentially stacked in the thickness direction.

Each of the first to third patterns may include a conductive material.

The first pattern may include a semiconductor material doped with an impurity to have conductivity.

The protective layer may include a material different from a material of the second pattern.

In accordance with another aspect of the disclosure, there is provided an electronic device including a processor to provide input image data, and a display device to display an image based on the input image data. The display device may include a pixel. The pixel may include: a first pattern disposed on a substrate; a lower insulating layer array including a lower penetration hole exposing a portion of the first pattern; a second pattern electrically in contact with the first pattern through the lower penetration hole, the second pattern including a recessed portion overlapping the lower penetration hole; a buffer layer filling the recessed portion; a protective layer interposed between the buffer layer and the second pattern in the recessed portion; an auxiliary conductive layer overlapping the lower penetration hole in a thickness direction, the auxiliary conductive layer covering the buffer layer and the second pattern adjacent to the buffer layer; an upper insulating layer array including an upper penetration hole exposing a portion of the auxiliary conductive layer; and a third pattern electrically in contact with the auxiliary conductive layer through the upper penetration hole.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that in case that an element is referred to as being “between” two elements, it can be the only element between the two elements, or one or more intervening elements may also be present. Like reference numerals refer to like elements throughout.

FIG. 1 is a schematic block diagram illustrating a display device in accordance with embodiments of the disclosure.

FIG. 2 is a schematic block diagram illustrating any one pixel among pixels included in the display device shown in FIG. 1.

FIGS. 3 and 4 are schematic views illustrating components constituting the pixel shown in FIG. 2.

FIG. 5 is a schematic plan view illustrating some of components constituting a sub-pixel circuit of the pixel shown in FIG. 2.

FIG. 6 is a schematic sectional view taken along line I1-I2 shown in FIG. 5.

FIG. 7 is a schematic plan view illustrating others of the components constituting the sub-pixel circuit of the pixel shown in FIG. 2.

FIG. 8 is a schematic sectional view taken along line I3-I4 shown in FIG. 7.

FIGS. 9 to 20 are schematic views illustrating a method of manufacturing the pixel.

FIG. 21 is a schematic block diagram illustrating an electronic device including a display device in accordance with an embodiment.

FIG. 22 is a schematic diagram illustrating an example where the electronic device of FIG. 21 is a smartphone.

FIG. 23 is a schematic diagram illustrating an example where the electronic device of FIG. 21 is a tablet computer.

### DETAILED DESCRIPTION OF THE EMBODIMENTS

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matters of the disclosure. In addition, the disclosure is not limited to embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, in case that an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that in case that a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

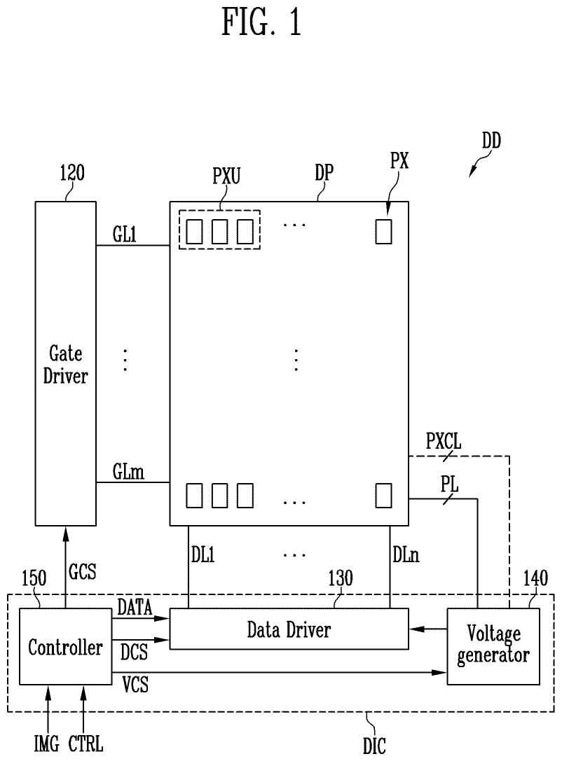

FIG. 1 is a schematic block diagram illustrating a display device in accordance with embodiments of the disclosure.

Referring to FIG. 1, the display device DD may include a display panel DP, a gate driver 120, a data driver 130, a voltage generator 140, and a controller 150.

The display panel DP may include pixels PX. The pixels PX may be electrically connected to the gate driver 120 through first to mth gate lines GL1 to GLm. The pixels PX may be electrically connected to the data driver 130 through first to nth data lines DL1 to DLn.

The pixels PX may generate multiple lights of colors. For example, each of the pixels PX may generate lights of red, green, blue, cyan, magenta, yellow, white, and the like.

Two or more pixels among the pixels PX may constitute a pixel unit PXU. For example, the pixel unit PXU may include three pixels as shown in FIG. 1. The pixel unit PXU may emit lights of various colors with various luminances according to a combination of lights emitted from the pixels included in the pixel unit PXU. However, embodiments are not limited thereto. In another example, the pixel unit PXU may include more than three or less than three pixels.

The gate driver 120 may be electrically connected to the pixels PX arranged in a row direction through the first to mth gate lines GL1 to GLm. The gate driver 120 may output gate signals to the first to mth gate lines GL1 to GLm in response to a gate control signal GCS. The gate control signal GCS may include a start signal indicating a start of each frame, a horizontal synchronization signal, and the like.

The gate driver 120 may be disposed at one side of the display panel DP. However, embodiments are not limited thereto. For example, the gate driver 120 may be divided into two or more drivers which are physically and/or logically divided, and these drivers may be disposed at one side of the display panel DP and the other side of the display panel DP, which is opposite to the one side. As such, in some embodiments, the gate driver 120 may be disposed in various forms at the periphery of the display panel DP.

The data driver 130 may be electrically connected to the pixels PX arranged in a column direction through the first to nth data lines DL1 to DLn. The data driver 130 may receive image data DATA and a data control signal DCS from the controller 150. The data driver 130 may operate in response to the data control signal DCS. The data control signal DCS may include a source start pulse, a source shift clock, a source output enable signal, and the like.

The data driver 130 may receive voltages from the voltage generator 140. The data driver 130 may apply data signals having grayscale voltages corresponding to the image data DATA to the first to nth data lines DL1 to DLn by using the received voltages. In case that a gate signal is applied to each of the first to mth gate lines GL1 to GLm, data signals corresponding to the image data DATA may be applied to the first to nth data line DL1 to DLn. Accordingly, corresponding pixels PX may generate light corresponding to the data signals, and the display panel DP may display an image.

The gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device DD. The voltage generator 140 may generate a plurality of voltages by receiving an input voltage from the outside of the display device DD and regulating the received voltage.

The voltage generator 140 may generate a first power voltage and a second power voltage. The generated first and second power voltages may be provided to the pixels PX through power lines PL. In other embodiments, at least one of the first and second power voltages may be provided from the outside of the display device DD.

Besides, the voltage generator 140 may provide various voltages and/or signals. For example, the voltage generator 140 may provide one or more initialization voltages applied to the pixels PX. For example, in a sensing operation for sensing electrical characteristics of transistors and/or light emitting elements of the pixels PX, a predetermined reference voltage may be applied to the first to nth data lines DL1 to DLn, and the voltage generator 140 may generate the reference voltage and transfer the reference voltage to the data driver 130. For example, in a display operation for displaying an image on the display panel DP, common pixel control signals may be applied to the pixels PX, and the voltage generator 140 may generate the pixel control signals. The voltage generator 140 may provide the pixel control signals to the pixels PX through pixel control lines PXCL. In FIG. 1, it is illustrated that the pixel control lines PXCL are electrically connected between the voltage generator 140 and the display panel DP. However, embodiments are not limited thereto. For example, the pixel control lines PXCL may be electrically connected between the gate driver 120 and the display panel DP. The pixel control signals may be transferred to the pixel control lines PXCL through the gate driver 120 from the voltage generator 140.

The controller 150 may control overall operations of the display device DD. The controller 150 may receive, from external sources, input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. The controller 150 may align the input image data IMG to be suitable for the pixels PXL in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The driver integrated circuit DIC may be disposed outside of the display panel DP. The data driver 130, the voltage generator 140, and the controller 150 may be components functionally divided in one driver integrated circuit DIC. In another embodiments, at least one of the data driver 130, the voltage generator 140, and the controller 150 may be provided as a component distinguished from the driver integrated circuit DIC.

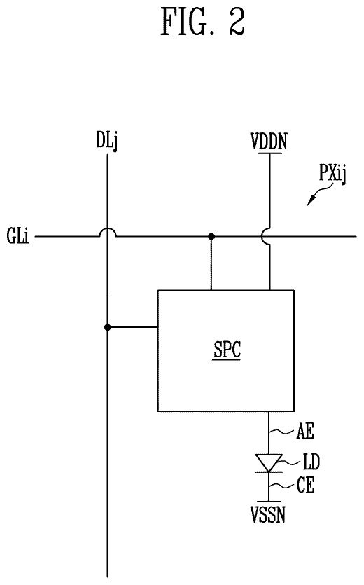

FIG. 2 is a schematic block diagram illustrating one pixel among the pixels PX included in the display device shown in FIG. 1. In FIG. 2, a pixel PXij arranged on an ith row (i is an integer greater than or equal to 1 and smaller than or equal to m) and a jth column (j is an integer greater than or equal to 1 and smaller than or equal to n) among the pixels PX shown in FIG. 1 is illustrated.

Referring to FIG. 2, the pixel PXij may include a sub-pixel circuit SPC and a light emitting element LD.

The light emitting element LD may be electrically connected between a first power voltage node VDDN and a second power voltage node VSSN. The first power voltage node VDDN may be electrically connected to one of the power lines PL shown in FIG. 1, to receive a first power voltage. The second power voltage node VSSN may be electrically connected to another of the power lines PL, to receive a second power voltage. The first power voltage may have a voltage level which is higher than a voltage level of the second power voltage.

The light emitting element LD may be electrically connected between an anode electrode AE and a cathode electrode CE. The anode electrode AE may be electrically connected to the first power voltage node VDDN through the sub-pixel circuit SPC. For example, the anode electrode AE may be electrically connected to the first power voltage node VDDN through one or more transistors included in the sub-pixel circuit SPC. The cathode electrode CE may be electrically connected to the second power voltage node VSSN. The light emitting element LD may be configured to emit light according to a current flowing from the anode electrode AE to the cathode electrode CE.

The sub-pixel circuit SPC may be electrically connected to an ith gate line GLi among the first to mth gate lines GL1 to GLm shown in FIG. 1 and a jth data line DLj among the first to nth data lines DL1 to DLn shown in FIG. 1. For example, the gate lines GL1 to GLm may extend in the first direction DR1, and the data lines DL1 to DLn may extend in the second direction DR2. However, embodiments are not limited thereto. In response to a gate signal received through the ith gate line GLi, the sub-pixel circuit SPC may control the light emitting element LD to emit light according to a data signal received through the jth data line DLj. The sub-pixel circuit SPC may be further connected to the pixel control lines PXCL shown in FIG. 1. The sub-pixel circuit SPC may control the light emitting element LD in further response to control signals received through the pixel control lines PXCL.

For these operations, the sub-pixel circuit SPC may include circuit elements, e.g., transistors and one or more capacitors.

The transistors of the sub-pixel circuit SPC may include P-type transistors and/or N-type transistors. The transistors of the sub-pixel circuit SPC may include a Metal Oxide Silicon Field Effect Transistor (MOSFET). The transistors of the sub-pixel circuit SPC may include an amorphous silicon semiconductor, a monocrystalline silicon semiconductor, polycrystalline silicon semiconductor, an oxide semiconductor, and the like.

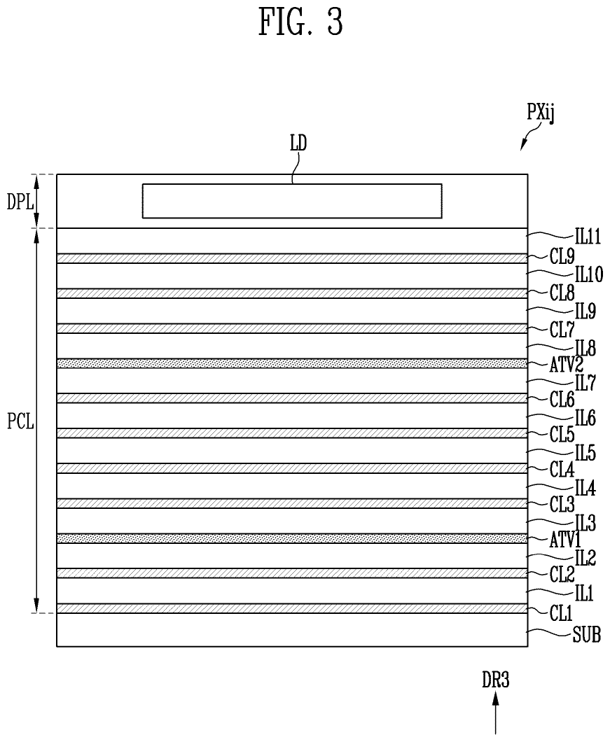

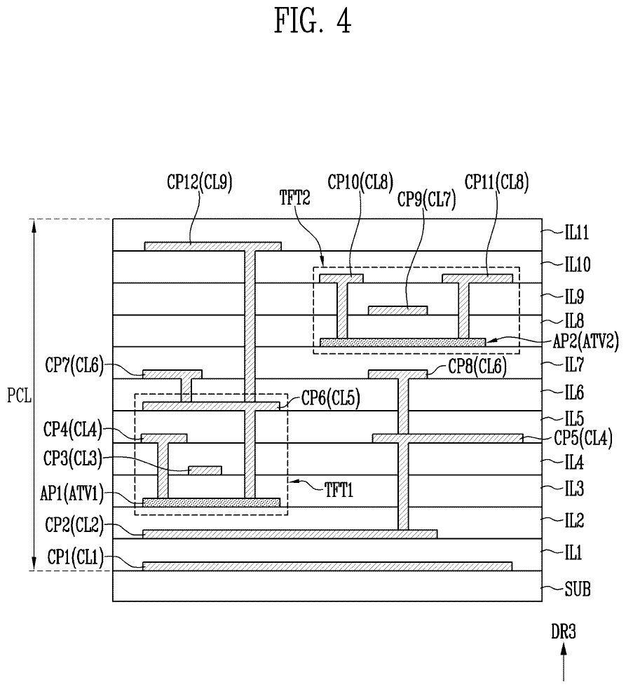

FIGS. 3 and 4 are schematic views illustrating components constituting the pixel shown in FIG. 2.

Referring to FIG. 3, the pixel PXij may include a pixel circuit layer PCL and a display element layer DPL, which are sequentially stacked along a third direction DR3 on a substrate SUB.

The substrate SUB may be made of various materials such as glass, polymer, and metal. The substrate SUB may be selected as one of a rigid substrates and a flexible substrate according to an application product. In case that the substrate SUB includes a polymer organic material, the substrate SUB may be formed of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate, or the like. On the other hand, in case that the substrate SUB may be made of fiber glass reinforced plastic (FRP).

The pixel circuit layer PCL may have a structure in which a first conductive layer CL1, a first insulating layer IL1, a second conductive layer CL2, a second insulating layer IL2, a first semiconductor layer ATV1, a third insulating layer IL3, a third conductive layer CL3, a fourth insulating layer IL4, a fourth conductive layer CL4, a fifth insulating layer IL5, a fifth conductive layer CL5, a sixth insulating layer IL6, a sixth conductive layer CL6, a seventh insulating layer IL7, a second semiconductor layer ATV2, an eighth insulating layer IL8, a seventh conductive layer CL7, a ninth insulating layer IL9, an eighth conductive layer CL8, a tenth insulating layer IL10, a ninth conductive layer CL9, and an eleventh insulating layer IL11 are sequentially stacked along the third direction DR3. For example, the first conductive layer CL1 may be disposed on the substrate SUB, the first insulating layer IL1 may be disposed on the first conductive layer CL1, the second conductive layer CL2 may be disposed on the first insulating layer IL1, the second insulating layer IL2 may be disposed on the first insulating layer IL1, the first semiconductor layer ATV1 may be disposed on the second insulating layer IL2, the third insulating layer IL3 may be disposed on the first semiconductor layer ATV1, the third conductive layer CL3 may be disposed on the third insulating layer IL3, the fourth insulating layer IL4 may be disposed on the third conductive layer CL3, the fourth conductive layer CL4 may be disposed on the third conductive layer CL3, the fifth insulating layer IL5 may be disposed on the fourth conductive layer CL4, the fifth conductive layer CL5 may be disposed on the fifth insulating layer IL5, the sixth insulating layer IL6 may be disposed on the fifth conductive layer CL5, the sixth conductive layer CL6 may be disposed on the sixth insulating layer IL6, the seventh insulating layer IL7 may be disposed on the sixth conductive layer CL6, the second semiconductor layer ATV2 may be disposed on the seventh insulating layer IL7, the eighth insulating layer IL8 may be disposed on the second semiconductor layer ATV2, the seventh conductive layer CL7 may be disposed on the eighth insulating layer IL8, the ninth insulating layer IL9 may be disposed on the seventh conductive layer CL7, the eighth conductive layer CL8 may be disposed on the ninth insulating layer IL9, the tenth insulating layer IL10 may be disposed on the eighth conductive layer CL8, the ninth conductive layer CL9 may be disposed on the tenth insulating layer IL10, and the eleventh insulating layer IL11 may be disposed on the ninth conductive layer CL9.

The first and second semiconductor layers ATV1 and ATV2 may include a semiconductor material. For example, the first semiconductor layer ATV1 may be formed of a poly-silicon semiconductor, and the second semiconductor layer ATV2 may be formed of an oxide semiconductor. An impurity for electric conduction may be doped into portions of the first and second semiconductor layers ATV1 and ATV2.

The first to ninth conductive layers CL1 to CL9 may include a conductive material. Each of the first to ninth conductive layers CL1 to CL9 may be independently formed as a single layer or a multi-layer, and be made of a conductor known in the art, such as gold (Au), silver (Ag), aluminum (Al), molybdenum (Mo), chromium (Cr), titanium (Ti), nickel (Ni), neodymium (Nd), copper (Cu), or platinum (Pt).

The first to eleventh insulating layers IL1 to IL11 may be interposed to electrically separate the first to ninth conductive layers CL1 to CL9 and the first and second semiconductor layers ATV1 and ATV2 from each other. All or some of these layers among the conductive layers CL1 to CL9 and the semiconductor layers ATV1 and ATV2 may be electrically connected to each other through a penetration hole formed in each of the insulating layers IL1 to IL11. Each of the first to eleventh insulating layers IL1 to IL11 may be independently formed of an organic insulating layer, an inorganic insulating layer, an organic/inorganic insulating layer, or the like, and be formed as a single layer or a multi-layer. For example, the first to eleventh insulating layers IL1 to IL11 may include at least one of silicon oxide, silicon nitride, silicon oxynitride, acrylic resin, epoxy resin, phenolic resin, polyamide resin, and polyimide resin.

Various components constituting the sub-pixel circuit SPC (see FIG. 2) may be implemented by the first and second semiconductor layers ATV1 and ATV2 and the first to ninth conductive layers CL1 to CL9, which are included in the pixel circuit layer PCL. For example, a transistor, a capacitor, a line, an electrode, and the like, which constitute the sub-pixel circuit SPC (see FIG. 2), may be implemented by the first and second semiconductor layers ATV1 and ATV2 and the first to ninth conductive layers CL1 to CL9.

The display element layer DPL may include a light emitting element LD, an anode electrode (AE shown in FIG. 2), and a cathode electrode (CE shown in FIG. 2). The anode electrode AE of the display element layer DPL may be electrically connected to the sub-pixel circuit SPC implemented by various components of the pixel circuit layer PCL. The light emitting element LD may be electrically connected to the anode electrode AE and the cathode electrode CE. The light emitting element LD may be configured to emit light according to a current flowing from the anode electrode AE to the cathode electrode CE.

Referring to FIG. 4, a transistor, a capacitor, a line, an electrode, and the like, which constitute the sub-pixel circuit SPC (see FIG. 2), may be implemented by the first and second semiconductor layers ATV1 and ATV2 and the first to ninth conductive layers CL1 to CL9.

For example, first to twelfth conductive patterns CP1 to CP12 may be implemented by the first to ninth conductive layers CL1 to CL9, and first and second semiconductor patterns AP1 and AP2 may be implemented by the first and second semiconductor layers ATV1 and ATV2. All or some of these patterns among the first to twelfth conductive patterns CP1 to CP12 and the first and second semiconductor patterns AP1 and AP2 may be electrically connected to each other through penetration holes formed in each of the insulating layers IL1 to IL11.

The first conductive pattern CP1 and the second conductive patterns CP2 may be disposed to overlap each other in the third direction DR3. The first conductive pattern CP1 and the second conductive patterns CP2 may constitute, for example, a capacitor.

The first semiconductor pattern AP1, the third conductive pattern CP3, the fourth conductive pattern CP4, and the sixth conductive pattern CP6 may constitute a first transistor TFT1. The third conductive pattern CP3 may constitute a gate electrode of the first transistor TFT1, the fourth conductive pattern CP4 may constitute a first electrode of the first transistor TFT1, and the sixth conductive pattern CP6 may constitute a second electrode of the first transistor TFT1. Some portions of the first semiconductor pattern AP1, which overlap the third conductive pattern CP3 along the third direction DR3, may constitute a channel of the first transistor TFT1.

The second semiconductor pattern AP2, the ninth conductive pattern CP9, the tenth conductive pattern CP10, and the eleventh conductive pattern CP11 may constitute a second transistor TFT2. The ninth conductive pattern CP9 may constitute a gate electrode of the second transistor TFT2, the tenth conductive pattern CP10 may constitute a first electrode of the second transistor TFT2, and the eleventh conductive pattern CP11 may constitute a second electrode of the second transistor TFT2. Some portions of the second semiconductor pattern AP2, which overlap the ninth conductive pattern CP9 along the third direction DR3, may constitute a channel of the second transistor TFT2.

The seventh conductive pattern CP7 and the twelfth conductive pattern CP12 may be electrically connected to the sixth conductive pattern CP6. The seventh conductive pattern CP7 and the twelfth conductive pattern CP12 may serve as a line or electrode for transferring various types of signals.

The fifth conductive pattern CP5 may be electrically connected to the second conductive pattern CP2, and the eighth conductive pattern CP8 may be electrically connected to the fifth conductive pattern CP5. The fifth conductive pattern CP5 and the eighth conductive pattern CP8 may serve as a line or electrode for transferring various types of signals.

Meanwhile, although nine conductive layers CL1 to CL9 and two semiconductor layers ATV1 and ATV2 are illustrated in FIGS. 3 and 4, the number of conductive layers and semiconductor layers may increase as the number of layers for forming conductive patterns and/or semiconductor patterns increases. Alternatively, the number of conductive layers and semiconductor layers may decrease as the number of layers for forming conductive patterns and/or semiconductor patterns decreases. As such, the number of conductive layers and semiconductor layers may be variously changed according to a configuration of the sub-pixel circuit SPC.

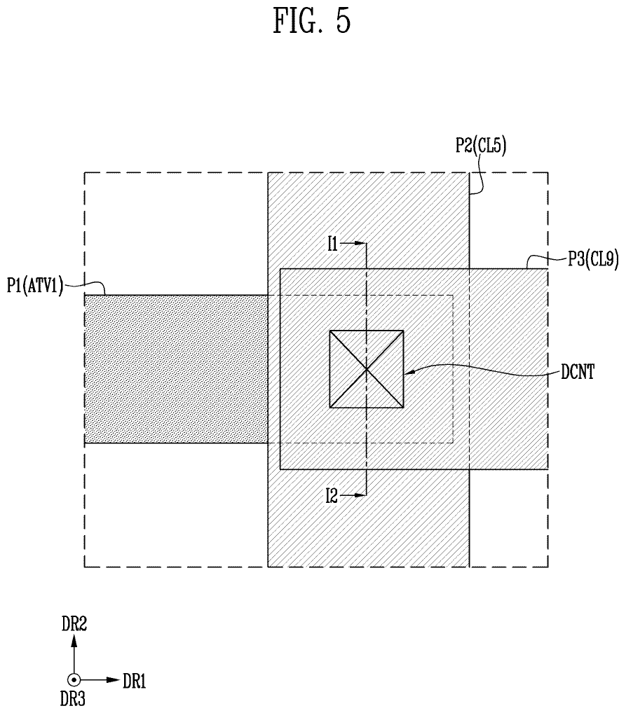

FIG. 5 is a schematic plan view illustrating some of components constituting the sub-pixel circuit of the pixel shown in FIG. 2.

Referring to FIG. 5, the sub-pixel circuit SPC of the pixel PXij may include first to third patterns P1, P2, and P3 sequentially disposed along the third direction DR3. The first pattern P1 may be implemented with, for example, the first semiconductor layer ATV1. The second pattern P2 may be implemented with, for example, the fifth conductive layer CL5. The third pattern P3 may be implemented with, for example, the ninth conductive layer CL9. However, the first to third patterns P1, P2, and P3 are not limited to the aforementioned description.

The first to third patterns P1, P2, and P3 may be electrically connected to each other. To this end, an overlapping penetration hole DCNT may be formed in insulating layers interposed between the first pattern P1, the second pattern P2, and the third pattern P3.

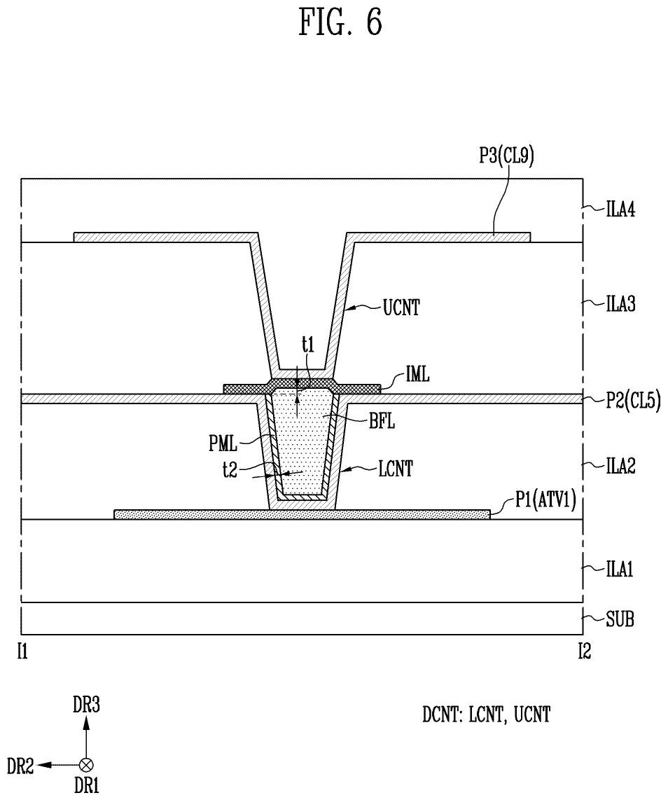

FIG. 6 is a schematic sectional view taken along line I1-I2 shown in FIG. 5.

Referring to FIG. 6, a first insulating layer array ILA1, a second insulating layer array ILA2, a third insulating layer array ILA3, and a fourth insulating layer array ILA4 may be sequentially disposed along the third direction DR3 on the substrate SUB.

The first insulating layer array ILA1 may include one or two or more insulating layers sequentially stacked along the third direction DR3. For example, the first insulating layer array ILA1 may include the first and second insulating layers IL1 and IL2 which have been described with reference to FIG. 3. A top surface (or upper surface) of the first insulating layer array ILA1 may be substantially flat.

The first pattern P1 may be disposed on the first insulating layer array ILA1. The first pattern P1 may be implemented with the first semiconductor layer ATV1. The first pattern P1 may be a portion doped with an impurity in the first semiconductor layer ATV1 to have conductivity.

The second insulating layer array ILA2 may be disposed on the first insulating layer array ILA1 to cover the first pattern P1. A lower penetration hole LCNT exposing a portion of the first pattern P1 may be defined in the second insulating layer array ILA2. The second insulating layer array ILA2 may include one or two or more insulating layers sequentially stacked along the third direction DR3. For example, the second insulating layer array ILA2 may include the third to fifth insulating layers IL3, IL4, and IL5 which have been described with reference to FIG. 3. A top surface (or upper surface) of the second insulating layer array ILA2 may be substantially flat.

The second pattern P2 may be disposed on the second insulating layer array ILA2. The second pattern P2 may be implemented with the fifth conductive layer CL5. The second pattern P2 may be electrically in contact with the first pattern P1 through the lower penetration hole LCNT. The second pattern P2 may have a shape corresponding to a profile of a section of the second insulating layer array ILA2 in which the lower penetration hole LCNT is formed. For example, the second pattern P2 may define a recessed portion corresponding to the lower penetration hole LCNT along the third direction DR3.

A buffer layer BFL may fill the recessed portion defined by the second pattern P2. The buffer layer BFL may include, for example, an organic insulating material. A protective layer PML may be interposed between the buffer layer BFL and the second pattern P2 in the recessed portion. The protective layer PML may include, for example, a material different from a material of the second pattern P2. For example, the protective layer PML may include a metal oxide. The buffer layer BFL may function to compensate for a step difference defined by the recessed portion.

A top surface (or upper surface) of the buffer layer BFL may be positioned higher than a top surface (or upper surface) of the second pattern P2. A thickness t1 between the top surface of the buffer layer BFL and the top surface of the second pattern P2 may be smaller than a thickness t2 of the protective layer PML.

An auxiliary conductive layer IML may be disposed on the buffer layer BFL along the third direction DR3 to overlap the lower penetration hole LCNT. The auxiliary conductive layer IML may cover the buffer layer BFL and the second pattern P2 adjacent to the buffer layer BFL. The auxiliary conductive layer IML may be in direct contact with the second pattern P2 adjacent to the buffer layer BFL. For example, the auxiliary conductive layer IML may be electrically in contact with the second pattern P2. The auxiliary conductive layer IML may be formed as a single layer or a multi-layer, and be made of a conductor known in the art, such as gold (Au), silver (Ag), aluminum (Al), molybdenum (Mo), chromium (Cr), titanium (Ti), nickel (Ni), neodymium (Nd), copper (Cu), or platinum (Pt).

The third insulating layer array ILA3 may be disposed on the second insulating layer array ILA2 along the third direction DR3 to cover the auxiliary conductive layer IML and the second pattern P2. An upper penetration hole UCNT exposing a portion of the auxiliary conductive layer IML may be defined in the third insulating layer array ILA3. The third insulating layer array ILA3 may include one or two or more insulating layers sequentially stacked along the third direction DR3. For example, the third insulating layer array ILA3 may include the sixth to tenth insulating layers IL6, IL7, IL8, IL9, and IL10 which have been described with reference to FIG. 3. A top surface (or upper surface) of the third insulating layer array ILA3 may be substantially flat.

The third pattern P3 may be disposed on the third insulating layer array ILA3. The third pattern may be implemented with the ninth conductive layer CL9. In this case, the third pattern P3 may be disposed along the surface of the third insulating layer array ILA3 and the upper penetration hole UCNT. Thus, the third pattern P3 may be electrically in contact with the auxiliary conductive layer IML through the upper penetration hole UCNT.

The fourth insulating layer array ILA4 may be disposed on the third insulating layer array ILA3 to cover the third pattern P3 along the third direction DR3. The fourth insulating layer array ILA4 may include one or two or more insulating layers sequentially stacked along the third direction DR3. For example, the fourth insulating layer array ILA4 may include the eleventh insulating layer IL11 which has been described with reference to FIG. 3. A top surface (or upper surface) of the fourth insulating layer array ILA4 may be substantially flat.

The buffer layer BFL, the protective layer PML, and the auxiliary conductive layer IML may function to compensate for the step difference defined by the recessed portion of the second pattern P2. Accordingly, the reliability of electrical connection of the three patterns P1, P2, and P3 disposed in different layers can be improved.

The lower penetration hole LCNT and the upper penetration hole UCNT may be disposed along the third direction DR3 while overlapping each other in a plan view. The lower penetration hole LCNT and the upper penetration hole UCNT may define the overlapping penetration hole DCNT. Accordingly, the area occupied by penetration holes DCNT for electrically connecting various components disposed in different layers within a limited area can be relatively reduced. Thus, the display device DD (see FIG. 1) having high PPI can be implemented.

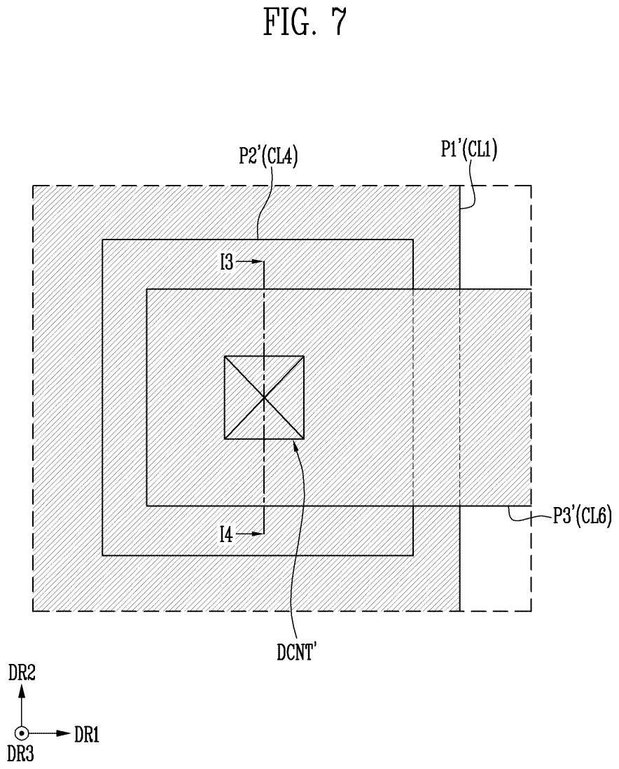

FIG. 7 is a plan view illustrating others of the components constituting the sub-pixel circuit of the pixel shown in FIG. 2.

Referring to FIG. 7, the sub-pixel circuit SPC of the pixel PXij may include first to third patterns P1′, P2′, and P3′ disposed along the third direction DR3. The first pattern P1′ may be implemented with, for example, the first conductive layer CL1. The second pattern P2′ may be implemented with, for example, the fourth conductive layer CL4. The third pattern P3′ may be implemented with, for example, the sixth conductive layer CL6. However, the first to third patterns P1′, P2′, and P3′ are not limited to the aforementioned description.

The first to third patterns P1′, P2′, and P3′ may be electrically connected to each other. In this case, an overlapping penetration hole DCNT′ may be formed in insulating layers interposed between the first pattern P1′ and the second pattern P2′ and insulating layers interposed between the second pattern P2′ and the third pattern P3′.

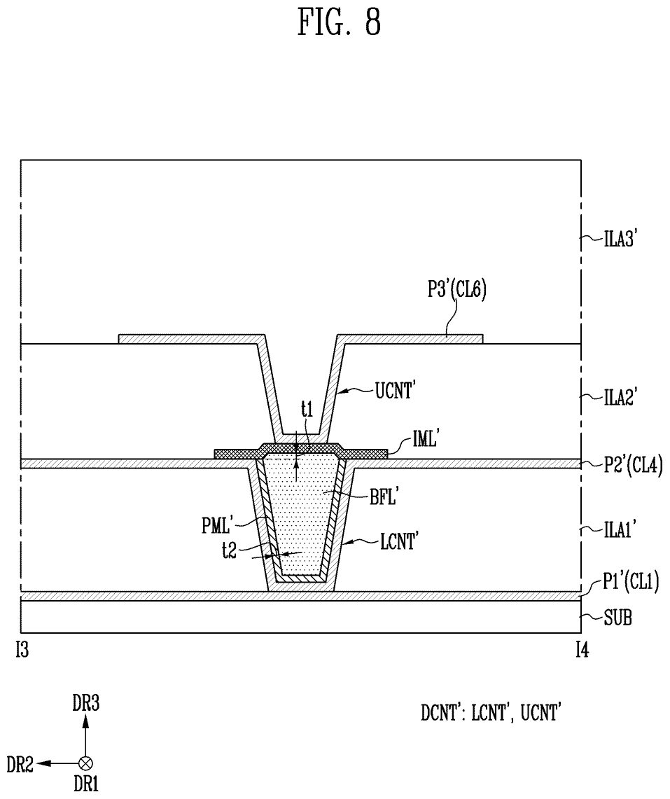

FIG. 8 is a schematic sectional view taken along line I3-I4 shown in FIG. 7.

Referring to FIG. 8, a first insulating layer array ILA1′, a second insulating layer array ILA2′, and a third insulating layer array ILA3′ may be disposed along the third direction DR3 on the substrate SUB.

The first pattern P1′ may be disposed on the substrate SUB. The first pattern P1′ may be implemented with the first conductive layer CL1.

The first insulating layer array ILA1′ may be disposed on the substrate SUB to cover the first pattern P1′. A lower penetration hole LCNT′ exposing a portion of the first pattern P1′ may be defined in the first insulating layer array ILA1′. The first insulating layer array ILA1′ may include one or two or more insulating layers sequentially stacked along the third direction DR3. For example, the first insulating layer array ILA1′ may include the first to fourth insulating layers IL1, IL2, IL3, and IL4 which have been described with reference to FIG. 3. A top surface (or upper surface) of the first insulating layer array ILA1′ may be substantially flat.

The second pattern P2′ may be disposed on the first insulating layer array ILA1′. The second pattern P2′ may be implemented with the fourth conductive layer CL4. The second pattern P2′ may be electrically in contact with the first pattern P1′ through the lower penetration hole LCNT′. The second pattern P2′ may have a shape corresponding to a profile of a section of the first insulating layer array ILA1′ in which the lower penetration hole LCNT′ is formed. For example, the second pattern P2′ may define a recessed portion corresponding to the lower penetration hole LCNT′.

A buffer layer BFL′ may fill the recessed portion defined by the second pattern P2′. The buffer layer BFL′ may include, for example, an organic insulating material. A protective layer PML′ may be interposed between the buffer layer BFL′ and the second pattern P2′ in the recessed portion. The protective layer PML′ may include, for example, a material different from a material of the second pattern P2′. For example, the protective layer PML′ may include a metal oxide. The buffer layer BFL′ may function to compensate for a step difference defined by the recessed portion.

A top surface (or upper surface) of the buffer layer BFL′ may be positioned higher than a top surface (or upper surface) of the second pattern P2′. A thickness t1 between the top surface (or upper surface) of the buffer layer BFL′ and the top surface (or upper surface) of the second pattern P2′ may be smaller than a thickness t2 of the protective layer PML′.

An auxiliary conductive layer IML′ may be disposed on the buffer layer BFL′ along the third direction DR3 to overlap the lower penetration hole LCNT′. The auxiliary conductive layer IML′ may cover the buffer layer BFL′ and the second pattern P2 adjacent to the buffer layer BFL′. The auxiliary conductive layer IML′ may be in direct contact with the second pattern P2′ adjacent to the buffer layer BFL′. For example, the auxiliary conductive layer IML′ may be electrically in contact with the second pattern P2′. The auxiliary conductive layer IML′ may be formed as a single layer or a multi-layer, and be made of a conductor known in the art, such as gold (Au), silver (Ag), aluminum (Al), molybdenum (Mo), chromium (Cr), titanium (Ti), nickel (Ni), neodymium (Nd), copper (Cu), or platinum (Pt).

The second insulating layer array ILA2′ may be disposed on the first insulating layer array ILA1′ along the third direction DR3 to cover the auxiliary conductive layer IML′ and the second pattern P2. An upper penetration hole UCNT′ exposing a portion of the auxiliary conductive layer IML′ may be defined in the second insulating layer array ILA2′. The second insulating layer array ILA2′ may include one or two or more insulating layers sequentially stacked along the third direction DR3. For example, the second insulating layer array ILA2′ may include the fifth and sixth insulating layers IL5 and IL6 which have been described with reference to FIG. 3. A top surface (or upper surface) of the second insulating layer array ILA2′ may be substantially flat.

The third pattern P3′ may be disposed on the second insulating layer array ILA2′. The third pattern P3′ may be implemented with the sixth conductive layer CL6. In this case, the third pattern P3′ may be disposed along the surface of the second insulating layer array ILA2′ and the upper penetration hole UCNT′. Thus, the third pattern P3′ may be electrically in contact with the auxiliary conductive layer IML′ through the upper penetration hole UCNT′.

The third insulating layer array ILA3′ may be disposed on the second insulating layer array ILA2′ to cover the third pattern P3′. The third insulating layer array ILA3′ may include one or two or more insulating layers sequentially stacked along the third direction DR3. For example, the third insulating layer array ILA3′ may include the seventh to eleventh insulating layers IL7, IL8, IL9, IL10, and IL11 which have been described with reference to FIG. 3. A top surface (or upper surface) of the third insulating layer array ILA3′ may be substantially flat.

The buffer layer BFL′, the protective layer PML′, and the auxiliary conductive layer IML′ may function to compensate for the step difference defined by the recessed portion. Accordingly, the reliability of electrical connection of the patterns P1′, P2′, and P3′ disposed in different layers can be improved.

In embodiments, the lower penetration hole LCNT′ and the upper penetration hole UCNT′ may be disposed while overlapping with each other in a plan view. The lower penetration hole LCNT′ and the upper penetration hole UCNT′ may define the overlapping penetration hole DCNT′. Accordingly, an area occupied by penetration holes for electrically connecting various components disposed in different layers within a limited area can be relatively reduced. Thus, the display device DD (see FIG. 1) having high PPI can be implemented.

Referring to FIGS. 5 to 8, various kinds of overlapping penetration holes DCNT and DCNT′ may be defined in the pixel circuit layer PCL of the disclosure. Accordingly, the display device DD (see FIG. 1) having high PPI can be implemented.

In addition, the buffer layer BFL or BFL′, the protective layer PML or PML′, and the auxiliary conductive layer IML and IML′ may be disposed to compensate for a step difference in the overlapping penetration hole DCNT or DCNT′ (e.g., a step difference caused by the recessed portion defined by the second pattern). Accordingly, the reliability of electrical connection of the patterns disposed in different layers can be improved.

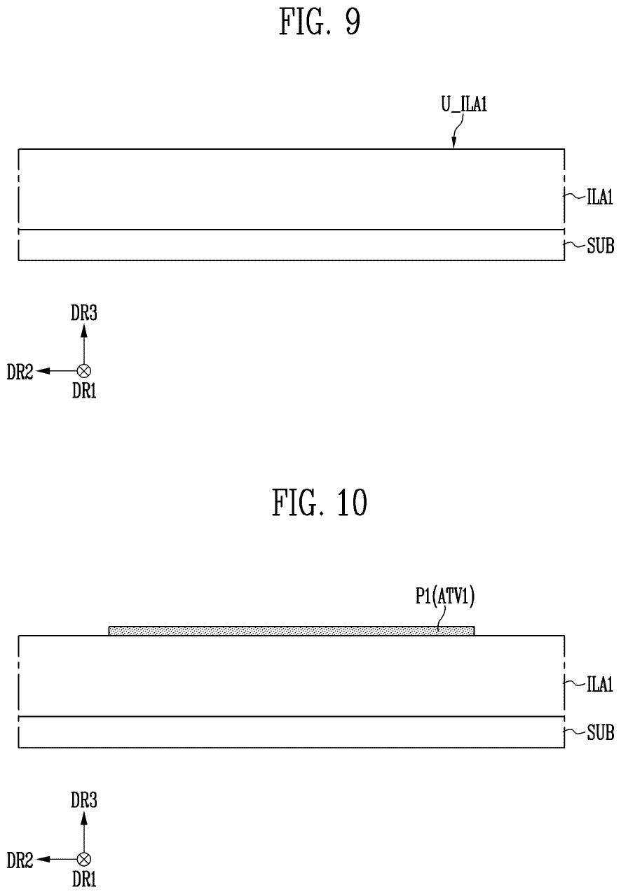

FIGS. 9 to 20 are views illustrating a method of manufacturing the pixel. Hereinafter, descriptions of components identical (or similar) to the components described with reference to FIGS. 5 and 6 may be omitted.

Referring to FIG. 9, a first insulating layer array ILA1 may be formed on a substrate SUB. In this step, a planarization process for planarizing a top surface (or upper surface) U_ILA1 of the first insulating layer array ILA1 may be performed. The planarization process is not limited, and various processes (e.g., a Chemical Mechanical Polishing (CMP) process) previously known in the art may be used to planarize the top surface U_ILA1 of the first insulating layer array ILA1.

Referring to FIG. 10, a first pattern P1 may be formed by patterning a first semiconductor layer ATV1. In this step, the first semiconductor layer ATV1 may be entirely formed on the first insulating layer array ILA1. Then, the first pattern P1 may be formed by partially removing the first semiconductor layer ATV1. In this case, the edge portions may be etched away, and the middle portion may be left.

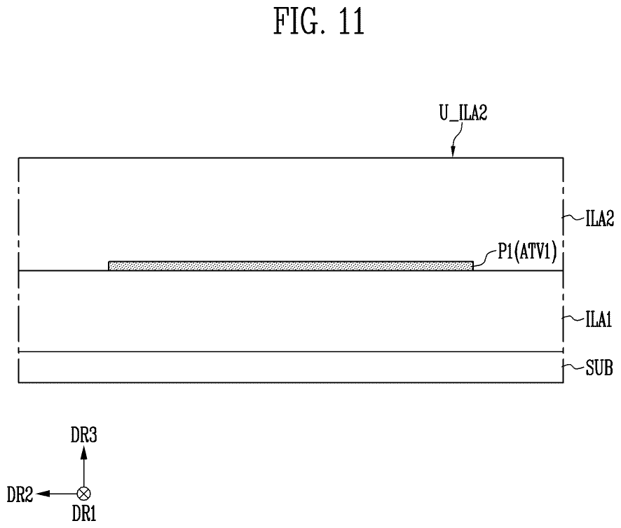

Referring to FIG. 11, a second insulating layer array ILA2 may be formed on the first insulating layer array ILA1 so that the second insulating layer array ILA2 may cover the first pattern P1. In this step, a planarization process for planarizing a top surface (or upper surface) U_ILA2 of the second insulating layer array ILA2 may be performed. The planarization process is not limited, and various processes (e.g., a CMP process) previously known in the art may be used to planarize the top surface U_ILA2 of the second insulating layer array ILA2.

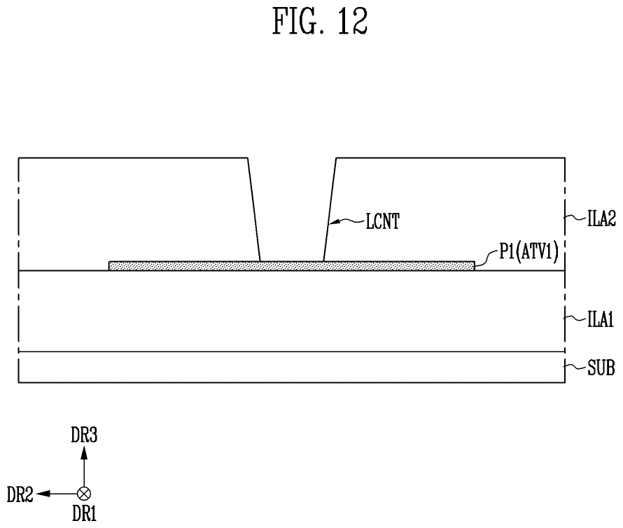

Referring to FIG. 12, a lower penetration hole LCNT exposing a portion of the first pattern P1 may be formed in the second insulating layer array ILA2. For example, a portion of the second insulating layer array ILA2 may be removed by a dry etching process using a partially etched photoresist layer as a mask so that the lower penetration hole LCNT may be formed.

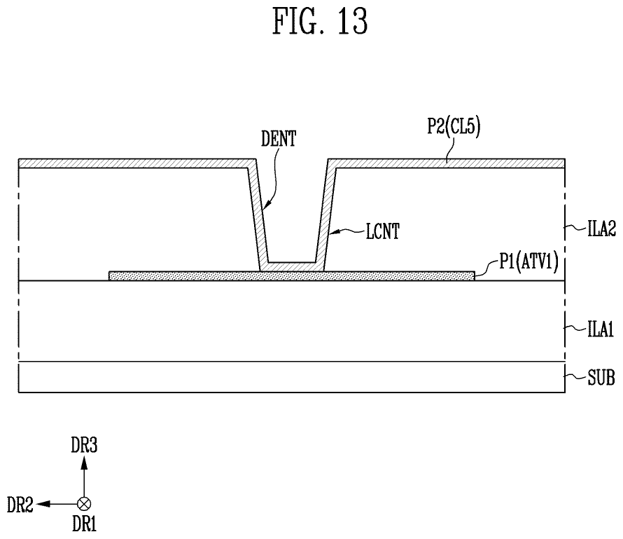

Referring to FIG. 13, a second pattern P2 may be formed on the second insulating layer array ILA2. The second pattern P2 may have a shape corresponding to a profile of a section of the second insulating layer array ILA2 in which the lower penetration hole LCNT is formed. For example, the second pattern P2 may define a recessed portion DENT corresponding to the lower penetration hole LCNT.

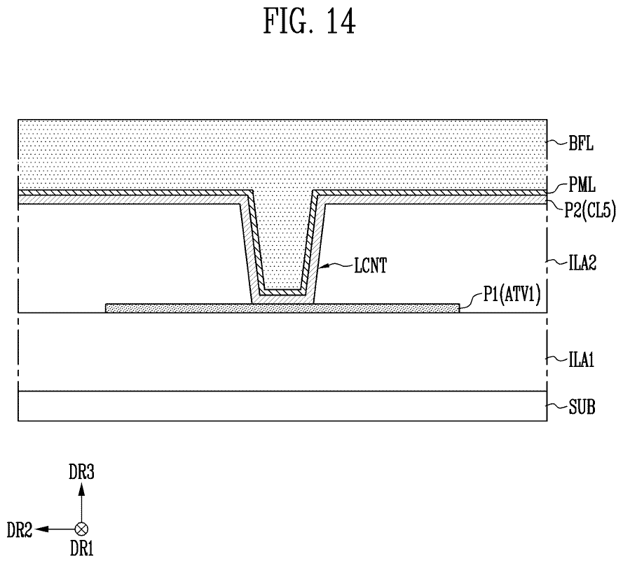

Referring to FIG. 14, a protective layer PML entirely covering the second pattern P2 may be formed. The protective layer PML may have a shape corresponding to a profile of a section of the second pattern P2. Thus, the protective layer PML may be disposed along the surface of the second pattern P2.

A buffer layer BFL entirely covering the protective layer PML may be formed. The buffer layer BFL may include, for example, an organic insulating material. In this step, the organic insulating material constituting the buffer layer BFL may be entirely applied on the protective layer PML. Therefore, the protective layer PML may be provided to fill the recessed portion DENT (see FIG. 13) defined by the second pattern P2.

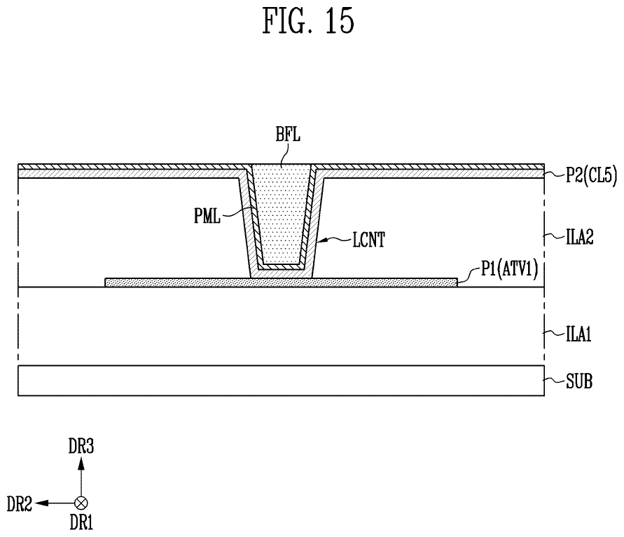

Referring to FIG. 15, a portion of the buffer layer BFL may be removed such that a top surface (or upper surface) of the protective layer PML is exposed, using a CMP process. The protective layer PML filling the recessed portion DENT (see FIG. 13) defined by the second pattern P2 may remain.

In this step, the protective layer PML may function to protect the second pattern disposed on the bottom of the protective layer PML in case that the CMP process is performed. For example, a top surface (or upper surface) of the second pattern P2 may not be exposed in case that the CMP process is performed. Accordingly, the second pattern P2 can be prevented from being removed by the CMP process.

To this end, as compared with the second pattern P2, the protective layer PML may include a material having high resistance against the CMP process. For example, the protective layer PML may include a material (e.g., a metal oxide) different from a material of the second pattern P2.

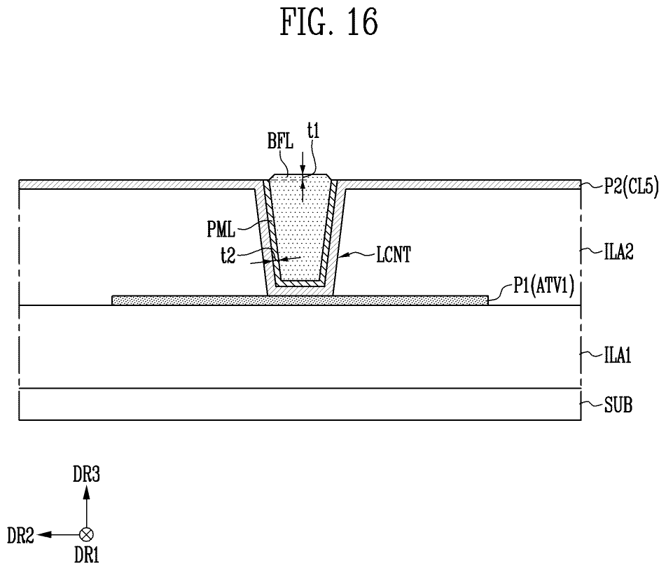

Referring to FIG. 16, the protective layer PML may be patterned. For example, the protective layer PML may be wet-etched. Accordingly, the protective layer PML except a portion interposed between the buffer layer BFL and the second pattern P2 of the protective layer PML may be removed by selectively patterning the protective layer.

In this step, after the protective layer PML is removed, a top surface (or upper surface) of the buffer layer BFL may be positioned higher than a top surface (or upper surface) of the second pattern P2. Since the CMP process is performed on the buffer layer BFL and the protective layer PML as has been described with reference to FIG. 15, a thickness t1 between the top surface of the buffer layer BFL and the top surface of the second pattern P2 may be smaller than a thickness t2 of the protective layer PML.

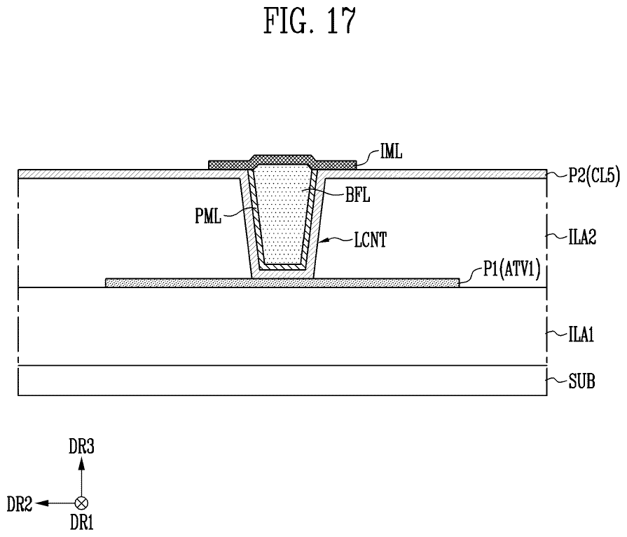

Referring to FIG. 17, an auxiliary conductive layer IML may be formed on the second pattern P2. The auxiliary conductive layer IML may cover the buffer layer BFL and the second pattern P2 adjacent to the buffer layer BFL while overlapping the lower penetration hole LCNT. The auxiliary conductive layer IML may be electrically in contact with the second pattern P2 adjacent to the buffer layer BFL.

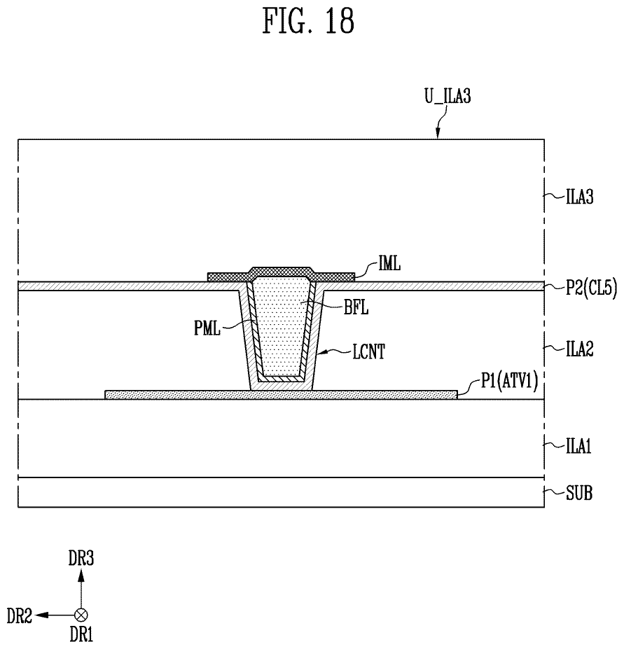

Referring to FIG. 18, a third insulating layer array ILA3 may be formed on the second insulating layer array ILA2. The third insulating layer array ILA3 may cover the second pattern P2 and the auxiliary conductive layer IML. In this step, a planarization process for planarizing a top surface (or upper surface) U_ILA3 of the third insulating layer array ILA3 may be performed. The planarization process is not limited, and various processes (e.g., a CMP process) previously known in the art may be used to planarize the top surface U_ILA3 of the third insulating layer array ILA3.

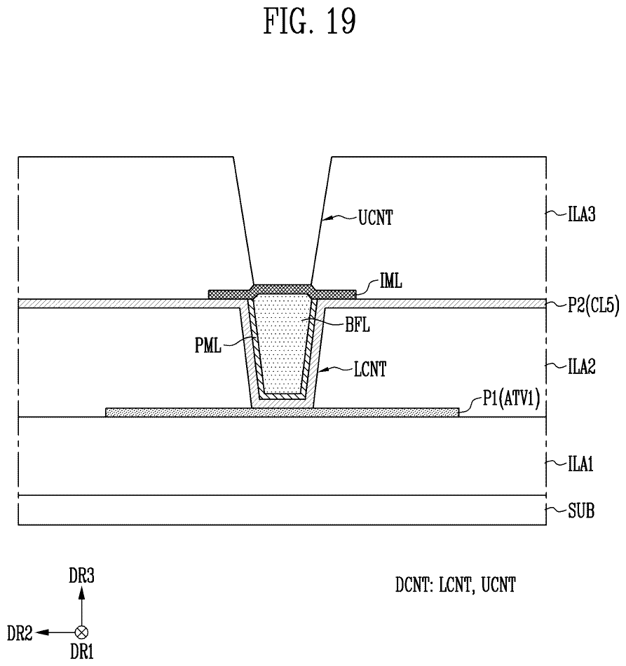

Referring to FIG. 19, an upper penetration hole UCNT exposing a portion of the auxiliary conductive layer IML may be formed in the third insulating layer array ILA3. For example, a portion of the third insulating layer array ILA3 may be removed by a dry etching process using a partially etched photoresist layer as a mask so that the upper penetration hole UCNT is formed.

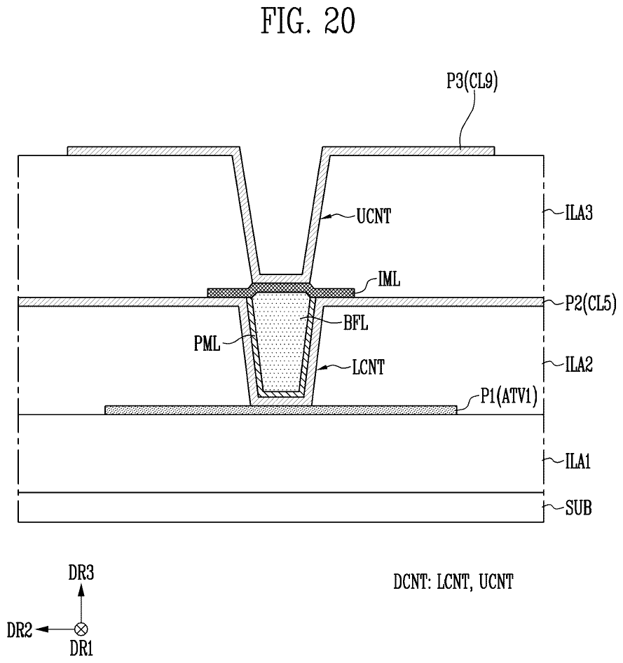

Referring to FIG. 20, a third pattern P3 may be formed by patterning a ninth conductive layer CL9. In this step, the ninth conductive layer CL9 is entirely formed on the third insulating layer array ILA3. Then, the third pattern P3 may be formed along the surface of the third insulating layer array ILA3 and the upper penetration hole UCNT by partially removing the ninth conductive layer CL9. The third pattern P3 may be electrically in contact with the auxiliary conductive layer IML through the upper penetration hole UCNT.

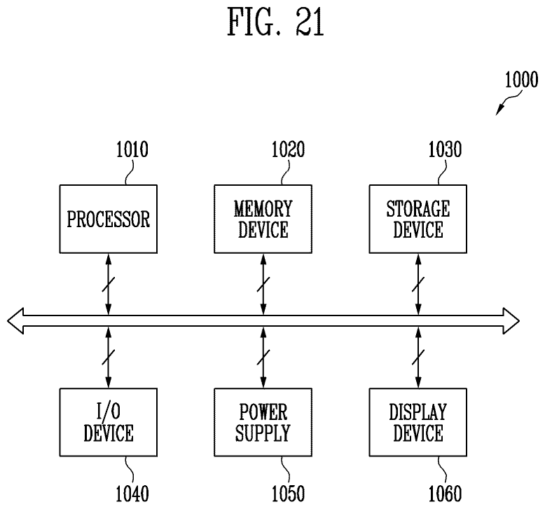

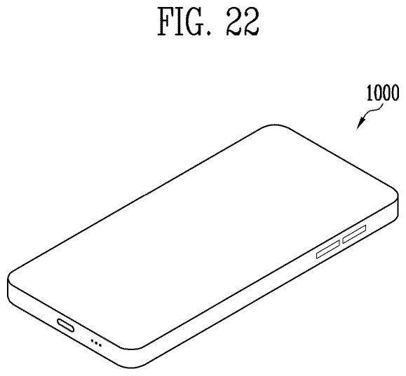

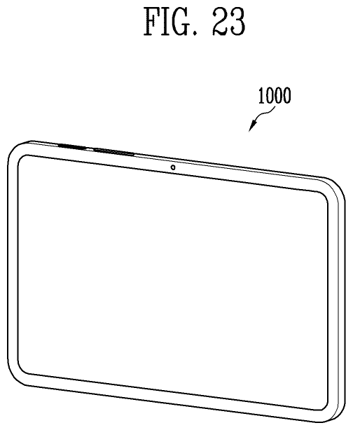

FIG. 21 is a schematic block diagram illustrating an electronic device including a display device in accordance with an embodiment. FIG. 22 is a schematic block diagram illustrating an example where the electronic device of FIG. 21 is a smartphone. FIG. 23 is a schematic block diagram illustrating an example where the electronic device of FIG. 21 is a tablet computer.

Referring to FIGS. 21 to 23, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 22, the electronic device 1000 may be a smartphone. In an embodiment, as illustrated in FIG. 23, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In an embodiment, the processor 1010 may be a microprocessor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be integrated with the I/O device 1040.

The power supply 1050 may supply power needed to perform the operation of the electronic device 1000. For example, the power supply 1050 may include a power management integrated circuit (PMIC). In an embodiment, the power supply 1050 may supply power to the display device 1060.

The display device 1060 may display images in response to control signals or data from the processor 1010. The display device 1060 may be connected to other components through the buses or other communication links.

In the pixel in accordance with the disclosure, a buffer layer, a protective layer, and an auxiliary conductive layer function to compensate for a step difference defined by a recessed portion of a second pattern. Accordingly, the reliability of electrical connection of first to third patterns disposed in different layers can be improved.

In the method of manufacturing the pixel in accordance with the disclosure, the protective layer functions to protect the second pattern in case that a Chemical Mechanical Polishing (CMP) process is performed. Accordingly, the reliability of the pixel can be prevented from being deteriorated as the second pattern is damaged in case that the CMP process is performed.

However, the effects of the disclosure are not restricted to the one set forth herein. The above and other effects of the disclosure will become more apparent to one of daily skill in the art to which the disclosure pertains by referencing the claims. The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the.

What is claimed is:

1. A pixel comprising:
a first pattern disposed on a substrate;
a lower insulating layer array including a lower penetration hole exposing a portion of the first pattern;
a second pattern electrically in contact with the first pattern through the lower penetration hole, the second pattern including a recessed portion overlapping the lower penetration hole;
a buffer layer filling the recessed portion;
a protective layer interposed between the buffer layer and the second pattern in the recessed portion;
an auxiliary conductive layer overlapping the lower penetration hole in a thickness direction, the auxiliary conductive layer covering the buffer layer and the second pattern adjacent to the buffer layer;
an upper insulating layer array including an upper penetration hole exposing a portion of the auxiliary conductive layer; and
a third pattern electrically in contact with the auxiliary conductive layer through the upper penetration hole.

2. The pixel of claim 1, wherein the lower penetration hole and the upper penetration hole are disposed and overlapped each other in a plan view.

3. The pixel of claim 1, wherein an upper surface of the lower insulating layer array is substantially flat.

4. The pixel of claim 1, wherein the protective layer includes a material different from a material of the second pattern.

5. The pixel of claim 4, wherein the protective layer includes a metal oxide.

6. The pixel of claim 1, wherein an upper surface of the buffer layer is positioned higher than an upper surface of the second pattern.

7. The pixel of claim 6, wherein a thickness between the upper surface of the buffer layer and the upper surface of the second pattern is smaller than a thickness of the protective layer.

8. The pixel of claim 1, wherein each of the lower insulating layer array and the upper insulating layer array includes two or more insulating layers which are sequentially stacked in the thickness direction.

9. The pixel of claim 1, wherein each of the first to third patterns includes a conductive material.

10. The pixel of claim 9, wherein the first pattern includes a semiconductor material doped with an impurity to have conductivity.

11. A method of manufacturing a pixel, the method comprising:
forming a first pattern on a substrate;
forming a lower insulating layer array on the first pattern;
selectively etching the lower insulating layer array to include a lower penetration hole exposing a portion of the first pattern;
forming a second pattern on the lower insulating layer array to electrically contact the first pattern through the lower penetration hole, the second pattern including a recessed portion corresponding to the lower penetration hole;
forming a protective layer on the second pattern to entirely cover the second pattern;
forming a buffer layer on the protective layer to entirely cover the protective layer and to fill the recessed portion;
removing a portion of the buffer layer such that an upper surface of the protective layer is exposed;
removing the protective layer except a portion interposed between the buffer layer and the second pattern in the recessed portion by selectively patterning the protective layer;
forming an auxiliary conductive layer on the second pattern to overlap the lower penetration hole in a thickness direction, the auxiliary conductive layer covering the buffer layer and the second pattern adjacent to the buffer layer;
forming an upper insulating layer array on the second pattern and the auxiliary conductive layer;
selectively etching the upper insulating layer array to define an upper penetration hole exposing a portion of the auxiliary conductive layer; and
forming a third pattern on the upper insulating layer array to electrically contact the auxiliary conductive layer through the upper penetration hole.

12. The method of claim 11, wherein the lower penetration hole and the upper penetration hole are disposed and overlapped each other in a plan view.

13. The method of claim 11, wherein the forming of the lower insulating layer array includes planarizing an upper surface of the lower insulating layer array.

14. The method of claim 11, wherein, in the removing of the buffer layer, an upper surface of the second pattern is not exposed.

15. The method of claim 11, wherein an upper surface of the buffer layer is positioned higher than an upper surface of the second pattern.

16. The method of claim 15, wherein a thickness between the upper surface of the buffer layer and the upper surface of the second pattern is smaller than a thickness of the protective layer.

17. The method of claim 11, wherein each of the lower insulating layer array and the upper insulating layer array includes two or more insulating layers which are sequentially stacked in the thickness direction.

18. The method of claim 11, wherein each of the first to third patterns includes a conductive material.

19. The method of claim 18, wherein the first pattern includes a semiconductor material doped with an impurity to have conductivity.

20. The method of claim 11, wherein the protective layer includes a material different from a material of the second pattern.

21. An electronic device comprising:
a processor to provide input image data; and
a display device to display an image based on the input image data, the display device including pixel,
wherein the pixel includes:
a first pattern disposed on a substrate;
a lower insulating layer array including a lower penetration hole exposing a portion of the first pattern;
a second pattern electrically in contact with the first pattern through the lower penetration hole, the second pattern including a recessed portion overlapping the lower penetration hole;
a buffer layer filling the recessed portion;
a protective layer interposed between the buffer layer and the second pattern in the recessed portion;
an auxiliary conductive layer overlapping the lower penetration hole in a thickness direction, the auxiliary conductive layer covering the buffer layer and the second pattern adjacent to the buffer layer;
an upper insulating layer array including an upper penetration hole exposing a portion of the auxiliary conductive layer; and
a third pattern electrically in contact with the auxiliary conductive layer through the upper penetration hole.
